(19) United States
(12) Patent Application Publication
(10) Pub. No.: US 2013/0161322 A1
(43) Pub. Date: Jun. 27, 2013

(54) HOUSING AND METHOD FOR MAKING THE SAME

(71) Applicants: XU-LEI LI, Shenzhen (CN); JIAN-MING LIU, Shenzhen (CN); JIAN-HUI DAI, Shenzhen (CN); CHUN-CHE YEN, New Taipei (TW); FENG-HSING HSIEH, New Taipei (TW)

(72) Inventors: XU-LEI LI, Shenzhen (CN); JIAN-MING LIU, Shenzhen (CN); JIAN-HUI DAI, Shenzhen (CN); CHUN-CHE YEN, New Taipei (TW); FENG-HSING HSIEH, New Taipei (TW)

(21) Appl. No.: 13/719,257

(22) Filed: Dec. 19, 2012

(30) Foreign Application Priority Data
Dec. 26, 2011 (CN) 201110440964.4

(51) Int. Cl. H05K 5/02; B44C 1/00

(52) U.S. Cl. CPC H05K 5/02; B44C 1/00
USPC 220/62.14; 427/265; 427/248.1; 428/35.7

(57) ABSTRACT

A plastic housing includes a plastic substrate and a decorative pattern layer attached on the plastic substrate. The decorative pattern layer includes an primer layer of a predetermined pattern formed on the plastic substrate and a colored pattern layer printed on the primer layer. The colored pattern layer is impervious to the color of the background color of the color layer, thus enabling housings with different colors to have substantially the same visual effects.

### BACKGROUND

1. Technical Field

The present disclosure relates to housings, particularly to a housing for electronic devices and a method for making the housing.

2. Description of Related Art

The appearance of portable electronic devices (such as mobile telephones and electronic notebooks) is very important in attracting consumers. Decorative patterns like text, logos or pictures can be formed on the external surface of housings of the portable electronic devices. There are many manufacturing method to make such decorative plastic housings, such as In-Mold Labeling (IML) process, laser etching process, and physical vapor deposition (PVD) process, etc.

To meet the color preferences of different groups of people, the same electronic device usually is equipped with a series of housings with different colors. But the decorative pattern arranged on the external surface of the housing needs to have the same shape and visual effects. The background color of the housing may interfere with the color of the decorative pattern, and because of this, housings of different colors do not appear to have the same visual effects. Therefore, there is room for improvement in the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 is an assembled, isometric view of an electronic device in accordance with an exemplary embodiment.

FIG. 2 is schematic cross-sectional view illustrating a housing of the electronic device of FIG. 1.

FIG. 3 is a series of schematic views illustrating a process for making the housing of the electronic device of FIG. 1.

FIG. 4 is a flowchart of a method for making a housing of the electronic device of FIG. 1.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean “at least one.”

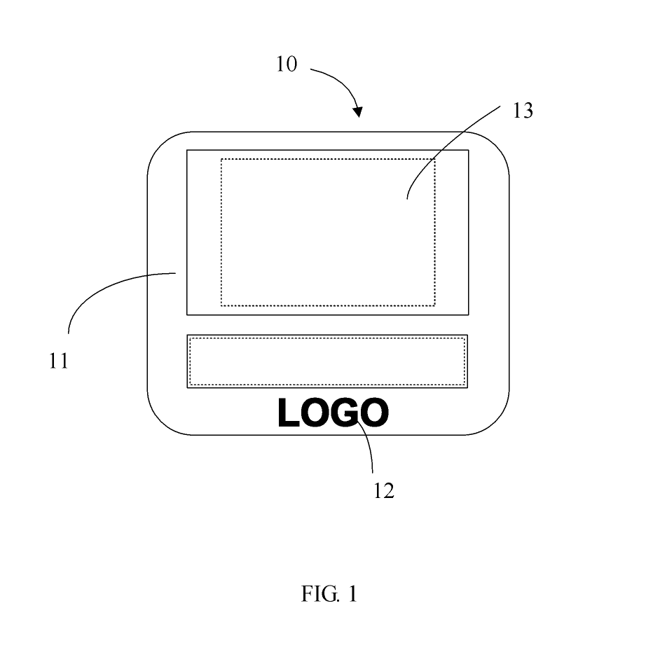

Referring to FIG. 1, an electronic device 10 is illustrated. The electronic device 10 can be a digital photo frame (DPF), an E-paper reading device, an MP3 player or a cell phone. The electronic device 10 includes a screen 13 and a housing 11 with a decorative pattern 12. In this embodiment, the decorative pattern 12 is a logo.

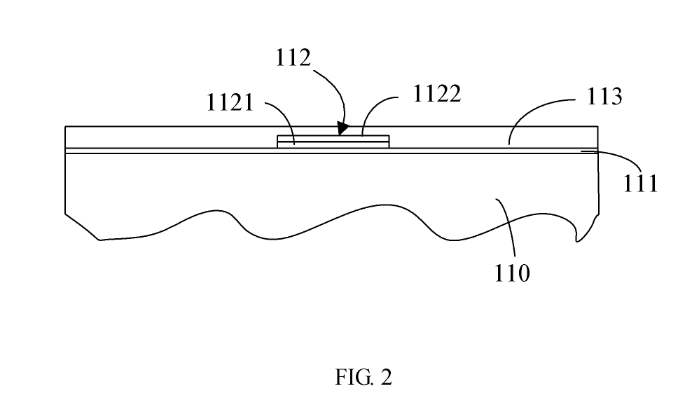

Referring to FIG. 2, the housing 11 includes a plastic substrate 110, a decorative pattern layer 112 and a transparent cover layer 113. The housing 11 further includes a color layer 111 on the external surface of the plastic substrate 110, the color layer 111 renders the housing capable of showing standard colors. A physical vapor deposition (PVD) process or a printing process can be employed to form the color layer 111 on the external surface of the plastic substrate 110. The color layer 111 is not limited to a monochromatic coating, and can be a colored pattern coating. In other embodiments, the plastic substrate 110 of the housing 11 may be made of colored plastic material.

The decorative pattern layer 112 is printed on the color layer 111, and appears as the decorative pattern 12. The decorative pattern layer 112 includes a prima layer 1121 having a single predetermined color, and a colored pattern layer 1121 overlaid the primer layer 1121, the primer layer 1121 and the colored pattern layer 1122 overlapping one another and having a same predetermined pattern.

The transparent cover layer 113 is arranged on the external surface of the plastic substrate 110 to cover the color layer 111 and the decorative pattern layer 112. The transparent cover layer 113 may be a transparent sheet attached on the base 110 by an adhesive (not shown) which is made of hot melt adhesive material. The transparent cover layer 113 may be made of a material selected from the group consisting of polyisoprene (PI), polycarbonate (PC), or polyethylene terephthalate (PET), or any suitable combination thereof. The thickness of the transparent cover layer 113 is in the range from 0.1 mm to 0.5 mm.

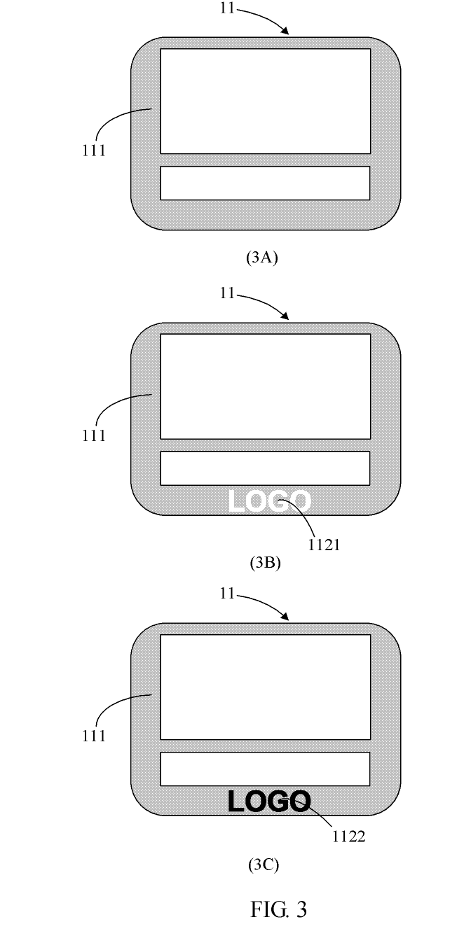

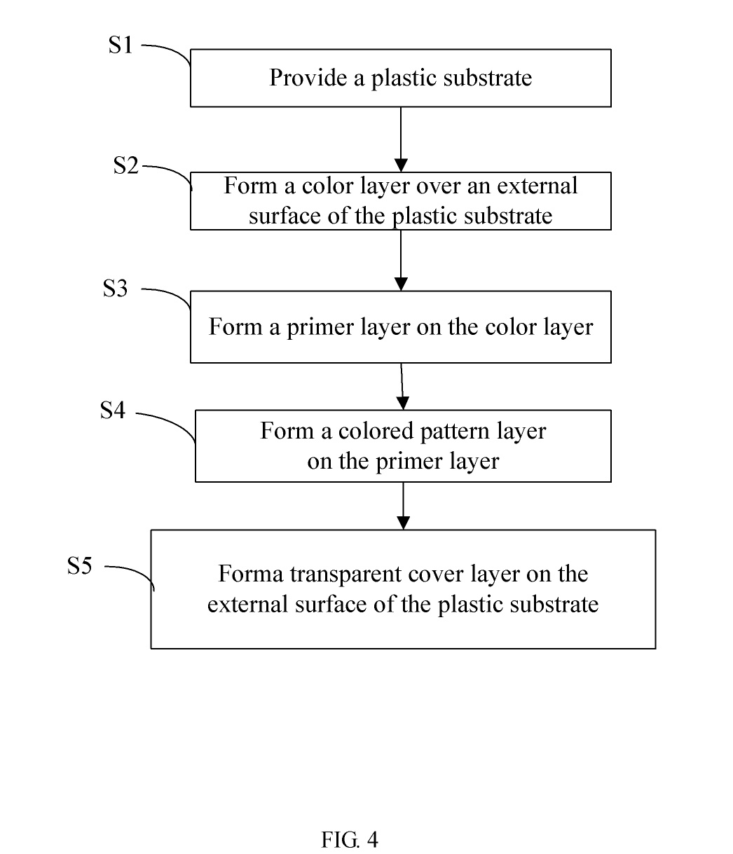

Referring to FIGS. 3 and 4, a process of making the housing 11 with a colored pattern layer 1122 according to an exemplary embodiment is illustrated.

In step S1, providing a plastic substrate 110.

In step S2, forming a color layer 111 over an external surface of the plastic substrate 110. Referring to FIG. 3A, a PVD process or a printing process can be employed to form the color layer 111 on the external surface of the plastic substrate 110.

In step S3, forming a primer layer 1121 of on the color layer 111, the primer layer 1121 having a same shape as the colored pattern layer 1122, the primer layer 1121 having a single predetermined color. Referring to FIG. 3B, the primer layer 1121 of the predetermined pattern is printed on the color layer 111. In this embodiment, the primer layer 1121 is a coating of white ink or dope. In other embodiments, the color of the primer layer 1121 may be black or other color.

In step S4, forming a colored pattern layer 1122 on the primer layer 1121, the colored pattern layer 1122 and the primer layer 1121 overlapping one another. Referring to FIG. 3B, a colored pattern layer 1122 having the same pattern as the primer layer 1121 is printed on the primer layer 1121, the colored pattern layer 1122 and the primer layer 1121 overlapping one another. The colored pattern layer 1122 has the same size and shape as the primer layer 1121.

In step S5, forming a transparent cover layer 113 on the external surface of the plastic substrate 110.

With such procedure and method, the colored pattern layer 1122 is not prejudiced or affected by the color of the color layer 111, since the colored pattern layer 1122 is separated from the color layer 111 by the primer layer 1121, which enables patterns 12 of housings 11 of different colors to present substantially the same visual effects without regard for the colors of the housings 11.

In another embodiment, the plastic substrate 110 of the housing 11 may be made of colored plastic material. In this case, the color layer 111 is omitted, and the decorative pattern 12 is directly formed on the plastic substrate 110.

In other embodiments, the primer layer 1121 may be an underpainting area forming a rectangle, ellipse or bar, and then the colored pattern layer 1122, such as a logo or a text, is printed over the area of the primer layer 1121.

It is to be understood, however, that even though numerous characteristics and advantages of the present disclosure have been set forth in the foregoing description, together with details of the structure and function of the present disclosure, the present disclosure is illustrative only, and changes may be made in detail, especially in the matters of shape, size, and arrangement of parts within the principles of the present disclosure to the full extent indicated by the broad general meaning of the terms in which the appended claims are expressed.

what is claimed is:

1. A method for forming a colored pattern layer on a substrate, comprising:
providing a plastic substrate;
forming a primer layer on an external surface of the plastic substrate, the primer layer having a same shape as the colored pattern layer, the primer layer having a single predetermined color; and
forming the colored pattern layer on the primer layer, the colored pattern layer and the primer layer overlapping one another.

2. The method according to claim 1, wherein the primer layer is formed on the plastic substrate using a printing process.

3. The method according to claim 1, wherein the colored pattern layer is formed on the primer layer using a printing process.

4. The method according to claim 1, further comprising: forming a transparent cover layer on the external surface of the plastic substrate to cover the colored pattern layer.

5. The method according to claim 4, wherein the transparent cover layer is made of a material selected from the group consisting of polyisoprene, polycarbonate, and polyethylene terephthalate.

6. The method according to claim 4, wherein a thickness of the transparent cover layer is in a range from about 0.1 mm to 0.5 mm.

7. A method for making a housing, comprising:
providing a plastic housing;
forming a color layer over an external surface of the housing;
forming a primer layer on the color layer, the primer layer having a same shape as a to-be-formed colored pattern layer, the primer layer having a single predetermined color; and
forming the colored pattern layer on the primer layer, the primer layer and the colored pattern layer overlapping one another.

8. The method according to claim 7, wherein the color layer is formed on the external surface of the plastic housing using a physical vapor deposition process or a printing process.

9. The method according to claim 7, wherein the primer layer is formed on the color layer using a printing process.

10. The method according to claim 8, further comprising: forming a transparent cover layer on the external surface of the plastic housing to cover the color layer and the colored pattern layer.

11. The method according to claim 10, wherein the transparent cover layer is made of a material selected from the group consisting of polyisoprene, polycarbonate, and polyethylene terephthalate.

12. The method according to claim 10, wherein a thickness of the transparent film is in the range from 0.1 mm to 0.5 mm.

13. A plastic housing comprising a plastic substrate and a decorative pattern layer on the plastic substrate, wherein the decorative pattern layer comprises a prima layer having a single predetermined color, and a colored pattern layer overlaid the primer layer, the primer layer and the colored pattern layer overlapping one another and having a same predetermined pattern.

14. The housing according to claim 13, further comprising a color layer formed over the external surface of the plastic substrate, wherein the primer layer is formed on the color layer.

15. The housing according to claim 13, wherein the decorative pattern layer is a logo.

16. The housing according to claim 13, further comprising a transparent cover layer attached on the external surface of the plastic substrate to cover the color layer and the decorative pattern layer.

17. The housing according to claim 16, wherein the transparent cover layer is made of a material selected from the group consisting of polyisoprene, polycarbonate, and polyethylene terephthalate.
